(19) United States
(12) Patent Application Publication
(10) Pub. No.: US 2025/0151602 A1
(43) Pub. Date: May 8, 2025

(54) ADHESIVE MEMBER AND FLEXIBLE DISPLAY DEVICE INCLUDING THE SAME

(71) Applicant: LG Display Co., Ltd., Seoul (KR)

(72) Inventor: Sang Ho JANG, Paju-si (KR)

(73) Assignee: LG Display Co., Ltd., Seoul (KR)

(21) Appl. No.: 18/749,808

(22) Filed: Jun. 21, 2024

(30) Foreign Application Priority Data
Nov. 7, 2023 (KR) 10-2023-0152723

(51) Int. Cl. H10K 77/10; B32B 3/30; B32B 7/12; C09J 7/30; C09J 9/00; C09J 201/00; H10K 59/80; H10K 102/00

(52) U.S. Cl. CPC H10K 77/111; B32B 3/30; B32B 7/12; C09J 7/30; C09J 9/00; C09J 201/00; H10K 59/8794; B32B 2307/546; B32B 2457/20; C09J 2301/21; C09J 2301/312; H10K 2102/311

(57) ABSTRACT

Embodiments of the disclosure relate to an adhesive member and a display device including the same and, more specifically, may provide a display device comprising a display panel assembly implementing an image, a supporting frame supporting a rear surface of the display panel assembly, and an adhesive member disposed between the display panel assembly and the supporting frame to couple the display panel assembly and the supporting frame, wherein the adhesive member has a protrusion pattern having different heights on one or two opposite surfaces thereof.

### CROSS-REFERENCE TO RELATED APPLICATION

This application claims the benefit and priority to Korean Patent Application No. 10-2023-0152723, filed in the Republic of Korea on Nov. 7, 2023, the entirety of which is hereby incorporated by reference for all purposes as if fully set forth herein.

### TECHNICAL FIELD

Embodiments of the disclosure relate to an adhesive member and a display device including the same.

### DISCUSSION OF THE RELATED ART

The advent of information era has led to a rapid advance in displays for visually expressing electrical information signals. Various display devices have accordingly been developed which are slim and lightweight, consume low power, and have excellent performance.

Specific examples of such display devices include liquid crystal display devices (LCDs), plasma display panel devices (PDPs), field emission display devices (FEDs), organic light emitting display devices (OLEDs) and the like.

Recently, flexible display devices which are manufactured of a flexible material, such as plastic, rather than a non-flexible material, e.g., glass substrate, as conventional, to be bendable like paper, but without deterioration of display performance, are rapidly attracting attention as a next-generation display device. Further, for commercial purposes and consumer needs, flexible display devices with a large area have been developed and commercialized in recent years.

Such a large-area flexible display device may largely include a display panel assembly for displaying an image, a support frame for supporting the rear surface of the display panel assembly, and an adhesive member for coupling the display panel assembly and the support frame. In this case, the adhesive member may be formed of double-sided tape and may be cut to fit the size of the display panel assembly. In other words, the adhesive member may be cut in proportion to the size of the display panel assembly.

The description provided in the background section should not be assumed to be prior art merely because it is mentioned in or associated with the background section. The background section may include information that describes one or more aspects of the subject technology.

### SUMMARY

It is newly recognized by inventors of the present disclosure that, as the display panel assembly becomes larger, the attachment area of the adhesive member also increases, which causes the problem that the display panel assembly and the adhesive member are not properly attached together and many air bubbles are formed between the display panel assembly and the adhesive member during the attachment process. In particular, more air bubbles tend to form in curved areas of the display panel assembly. Air bubbles forming between the display panel assembly and the adhesive member may swell as their internal pressure increases due to the heat generated when the display panel assembly is driven, leading to delamination between the display panel assembly and the supporting frame and deterioration of visibility of the display device.

Therefore, the inventors of the present disclosure recognized the limitations mentioned above and other limitations associated with the related art, and conducted various experiments to implement a display device capable of preventing or reducing formation of bubbles between a large-area display panel assembly and an adhesive member when attaching the adhesive member to the display panel assembly, for example, by forming micro irregular pattern for discharging air bubbles on the surface of the adhesive member.

Accordingly, embodiments of the present disclosure are directed to an adhesive member and a display device including the same that substantially obviates one or more of the problems due to limitations and disadvantages of the related art.

An aspect of the present disclosure is to provide a display device including an adhesive member having a pattern area having a protrusion pattern and a non-pattern area without a protrusion pattern, thereby enhancing adhesion through the non-pattern area while removing air bubbles formed between the display panel assembly and the adhesive member through the pattern area during an attachment process.

Another aspect of the present disclosure is to provide a display device capable of preventing or reducing delamination of the display panel assembly and deterioration of visibility due to air bubbles by minimizing or reducing air bubbles formed between the display panel assembly and the adhesive member.

Additional features and aspects of the disclosure will be set forth in the description that follows, and in part will be apparent from the description, or may be learned by practice of the inventive concepts provided herein. Other features and aspects of the inventive concepts may be realized and attained by the structures pointed out in the written description, or derivable therefrom, and the claims hereof as well as the appended drawings.

To achieve these and other aspects of the inventive concepts, as embodied and broadly described herein, an adhesive member, for coupling a display panel assembly implementing an image and a supporting frame supporting a rear surface of the display panel assembly, may comprise a base portion and an adhesive portion formed on one side or two opposite sides of the base portion and provided with a protrusion pattern having different heights.

In another aspect, a display device may comprises a display panel assembly implementing an image, a supporting frame supporting a rear surface of the display panel assembly, and an adhesive member disposed between the display panel assembly and the supporting frame to couple the display panel assembly and the supporting frame, wherein the adhesive member has a protrusion pattern having different heights on one or two opposite surfaces thereof.

According to embodiments of the disclosure, there may be provided a display device capable of preventing or reducing formation of bubbles between a large-area display panel assembly and an adhesive member when attaching the adhesive member to the display panel assembly by forming micro irregular pattern for discharging air bubbles on the surface of the adhesive member.

According to embodiments of the disclosure, there may be provided a display device capable of enhancing adhesion between the display panel assembly and the adhesive member by increasing the contact area with the display panel assembly by forming a micro irregular pattern on the surface of the adhesive member.

According to embodiments of the disclosure, there may be provided a display device capable of preventing or reducing delamination of the display panel assembly and deterioration of visibility due to air bubbles by minimizing or reducing air bubbles formed between the display panel assembly and the adhesive member.

According to embodiments of the disclosure, there may be provided a display device capable of implementing a uni-body product with simplified and unified components by coupling the display panel assembly and the supporting frame only with the adhesive member without fastening components, such as bolts.

It is to be understood that both the foregoing general description and the following detailed description are exemplary and explanatory and are intended to provide further explanation of the inventive concepts as claimed.

### DESCRIPTION OF DRAWINGS

The accompanying drawings, which are included to provide a further understanding of the disclosure and are incorporated in and constitute a part of this application, illustrate embodiments of the disclosure and together with the description serve to explain various principles of the disclosure.

FIG. 1 is a cross-sectional view illustrating an adhesive member according to an embodiment of the disclosure;

FIG. 2 is an exploded perspective view illustrating a display device according to an embodiment of the disclosure;

FIG. 3 is a view illustrating a process of attaching the adhesive member of FIG. 2 to a display panel assembly; and

FIGS. 4, 5, and 6 are cross-sectional views illustrating a shape of a protrusion pattern according to a curved structure of a flexible display device.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure. Further, the present disclosure is only defined by scopes of claims. Any implementation described herein as an “example” is not necessarily to be construed as preferred or advantageous over other implementations.

The shapes, sizes, ratios, angles, numbers, and the like, which are illustrated in the drawings to describe various example embodiments of the present disclosure are merely given by way of example. Therefore, the present disclosure is not limited to the illustrations in the drawings. The same or similar elements are designated by the same reference numerals throughout the specification unless otherwise specified. In the following description where the detailed description of the relevant known function or configuration may unnecessarily obscure an important point of the present disclosure, a detailed description of such known function of configuration may be omitted.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various embodiments of the disclosure are described in detail with reference to the accompanying drawings. Further, all the components of each adhesive member and each display device including the same according to all embodiments of the present disclosure are operatively coupled and configured. For convenience of description, a scale of each of elements illustrated in the accompanying drawings differs from a real scale, and thus, is not limited to a scale illustrated in the drawings.

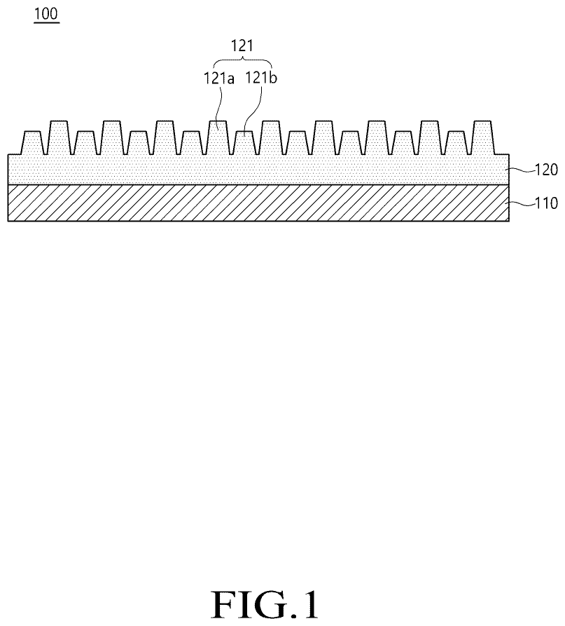

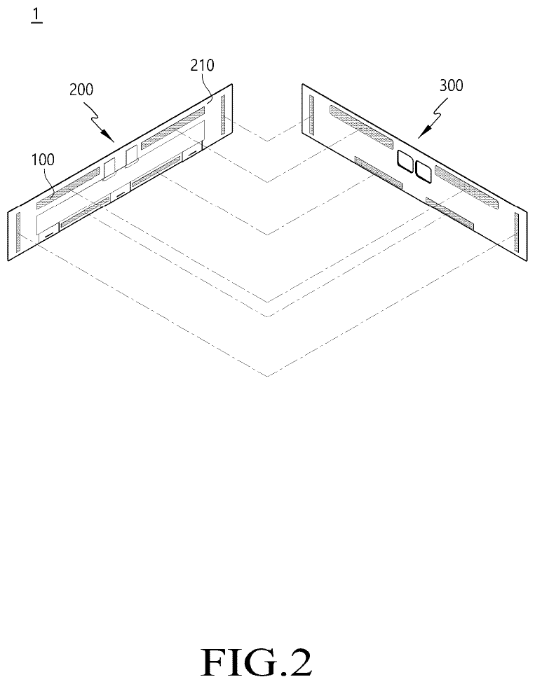

FIG. 1 is a cross-sectional view of an adhesive member according to an embodiment of the disclosure, and FIG. 2 is an exploded perspective view of a display device including the adhesive member of FIG. 1.

Referring to FIGS. 1 to 2, the adhesive member 100 is for coupling between the display panel assembly 200 implementing an image and the supporting frame 300 supporting the rear surface of the display panel assembly 200, and may include a base portion 110 and an adhesive portion 120.

The base portion 110 may be formed in a flat plate shape and may be formed of an insulating material. For example, the base portion 110 may be formed of a flexible material such as polyethylene terephthalate (PET), polyethylene naphthalate (PEN), polycarbonate (PC), or the like.

The adhesive portion 120 may be formed on one side or two opposite sides of the base portion 110, and may have a protrusion pattern 121 having different heights.

The protrusion pattern 121 may be formed in an irregular or uneven shape in which a plurality of protrusions are spaced apart from each other. For example, the adhesive member 100 may be provided in a state of being pre-attached to the display panel assembly 200. In this case, when air bubbles are formed between the display panel assembly 200 and the adhesive member 100, the air bubbles may swell due to heat generated when the display panel assembly 200 is driven. In this case, the display panel assembly 200 may be peeled off and visibility may be lowered. When the protrusion pattern 121 having an irregular or uneven structure having different heights is formed on the surface of the adhesive member 100 as in the present embodiment, air bubbles may be discharged through the space between the patterns during the attachment process. Accordingly, the adhesive strength between the display panel assembly 200 and the adhesive member 100 may be enhanced, thereby preventing or reducing the display panel assembly 200 from being peeled off and visibility from being deteriorated due to the generation of air bubbles.

Each of the protrusion patterns 121 may be formed in a tapered shape having a narrower width toward the end. Due to the shape of the protrusion pattern 121, a passage through which air bubbles may be discharged is formed between the protrusions, and more air bubbles may be discharged. Further, due to the tapered structure, interference between protrusions of the protrusion pattern 121 that are compressed and spread during the attachment process may be prevented or reduced. However, the present disclosure is not limited thereto, and for example, the protrusion patterns 121 may be formed in various other shapes other than the tapered shape.

An end portion of the protrusion pattern 121 may be formed in a straight line shape or a dome shape. When the end portion of the protrusion pattern 121 is formed in a straight line shape, the contact area with the object may increase, thereby increasing the adhesive force. Further, when the end portion of the protrusion pattern 121 is formed in a dome shape, the protrusion pattern 121 may be compressed better than in the straight line shape during the attachment process, thereby facilitating attachment.

The protrusion pattern 121 may include a first protrusion 121a and a second protrusion 121b.

The first protrusions 121a may protrude in one direction. A plurality of first protrusions 121a may be provided to be spaced apart from each other. Each second protrusions 121b may be disposed between the first protrusions 121a, and may protrude in a size smaller than the height of the first protrusions 121a.

The height of the second protrusion 121b may be formed to be at least half or less of the height of the first protrusion 121a. For example, the first protrusion 121a may be provided to have a height of 50 to 80 μm (specifically, 60 to 70 μm, or 65 μm), and the second protrusion 121b may be provided to have a height of 20 to 30 μm (specifically, 25 μm). When the height difference between the first protrusion 121a and the second protrusion 121b is less than 30 μm, the bubble removal efficiency may be reduced, and when the height difference between the first protrusion 121a and the second protrusion 121b exceeds 60 μm, the adhesive strength may be reduced.

As such, as the height of the second protrusion 121b is formed to be smaller, an air passage through which air may be discharged may be formed between the first protrusions 121a. Accordingly, air bubbles may be discharged through the air passage during the attachment process of the adhesive member 100, thereby enhancing the adhesive force between the supporting frame 300 or the display panel assembly 200, which is an object to be attached.

The sum of the maximum width of the first protrusion 121a and the maximum width of the second protrusion 121b may be at least 1,200 μm or less. For example, the sum of the maximum width of the first protrusion 121a and the maximum width of the second protrusion 121b may be provided as 1,000 to 1,200 μm. This is designed considering the heights of the first protrusion 121a and the second protrusion 121b, and when designed in this way, air bubbles generated during the attachment process may be seamlessly discharged while enhancing the adhesive force.

It is to be noted that although the irregular or uneven shape of the protrusion pattern 121 is formed through the alternatively arranged first and second protrusions 121a and 121b having different heights as shown in FIG. 1, the present disclosure is not limited thereto. For example, the first and second protrusions 121a and 121b may be irregularly arranged on the base portion 110. As another example, the second protrusions 121b may be omitted and only the first protrusions 121a are formed to be spaced apart from each other on the base portion 110. As yet another example, the adhesive portion 120 may have a plurality of grooves, holes, or concaved patterns regularly or irregularly arranged therein. In other words, the shapes or structures of the protrusion pattern 121 according to embodiments of the present disclosure are not limited to that shown in FIG. 1, and may have various other arrangements as long as there is an air passage through which air may be discharged formed in the protrusion pattern 121 during the attachment process of the adhesive member 100.

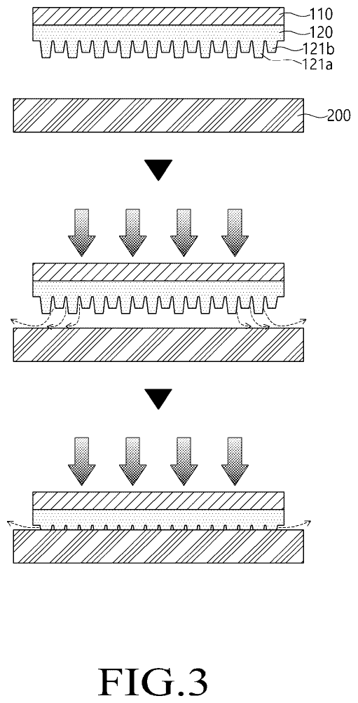

FIG. 2 is an exploded perspective view of a display device according to an embodiment of the disclosure, and FIG. 3 is a view illustrating a process of attaching the adhesive member of FIG. 2 to a display panel assembly. In this embodiment, the description focuses primarily on differences from the above-described embodiment.

Referring to FIGS. 2 to 3, the display device 1 may include an adhesive member 100, a display panel assembly 200, and a supporting frame 300.

The display panel assembly 200 is a component for implementing an image, and a light emitting element for implementing the image, a circuit for driving the light emitting element, lines, and components may be disposed thereon. FIG. 2 illustrates a rear surface of the display panel assembly 200, and although not illustrated, a display surface may be positioned on the front surface.

The supporting frame 300 may support a rear surface of the display panel assembly 200. The rear surface of the display panel assembly 200 may be protected through the supporting frame 300.

The adhesive member 100 may be disposed between the display panel assembly 200 and the supporting frame 300, and couple the display panel assembly 200 and the supporting frame 300. For example, the adhesive member 100 may be long disposed on a rear edge of the display panel assembly 200. The attachment position of the adhesive member 100 is not limited to the illustrated example, and may vary depending on the shape of the display panel assembly 200.

A protrusion pattern 121 having different heights may be formed on one surface or two opposite surfaces of the adhesive member 100. Specifically, the adhesive member 100 may include a base portion 110 and an adhesive portion 120 formed on one side or two opposite sides of the base portion 110 and provided with a protrusion pattern 121 having different heights. In other words, the protrusion pattern 121 may be formed by forming irregularities in which a plurality of protrusions are spaced apart from each other. Each of the protrusion patterns 121 may be formed in a tapered shape having a width decreasing toward the end, and the end portion may be formed in a straight line or dome shape.

The protrusion pattern 121 may include a first protrusion 121a and a second protrusion 121b.

The first protrusions 121a may protrude in one direction. A plurality of first protrusions 121a may be provided to be spaced apart from each other. Each second protrusions 121b may be disposed between the first protrusions 121a, and may protrude in a size smaller than the height of the first protrusions 121a. For example, the first protrusion 121a may be provided to have a height of 50 to 80 μm (specifically, 60 to 70 μm, or 65 μm), and the second protrusion 121b may be provided to have a height of 20 to 30 μm (specifically, 25 μm).

As such, as the protrusion pattern 121 having different heights is formed on one surface or two opposite surfaces of the adhesive member 100, air bubbles may be prevented or reduced from being formed between the display panel assembly 200 and the adhesive member 100 during the process of attaching the display panel assembly 200 and the adhesive member 100. In other words, as illustrated in FIG. 3, when the adhesive member 100 is brought into tight contact with one surface of the display panel assembly 200 and then pressed, air bubbles may be discharged through the space disposed between the first protrusions 121a. Accordingly, the adhesive strength between the display panel assembly 200 and the adhesive member 100 may be enhanced, thereby preventing or reducing the display panel assembly 200 from being peeled off and visibility from being deteriorated due to the generation of air bubbles.

Particularly, when the adhesive member 100 is attached to the display panel assembly 200 having a large area, more air bubbles may be formed. When the display panel assembly 200 and the supporting frame 300 are attached using the adhesive member 100 on which the protrusion pattern 121 is formed, the display panel assembly 200 may be stably coupled to the supporting frame 300 without delamination.

According to an embodiment of the disclosure, a heat dissipation plate 210 formed of, for example, but not limited to, a metal such as aluminum may be further provided on the rear surface of the display panel assembly 200. As such, when the heat dissipation plate 210 is provided on the rear surface of the display panel assembly 200, the adhesive member 100 may be disposed between the heat dissipation plate 210 and the supporting frame 300.

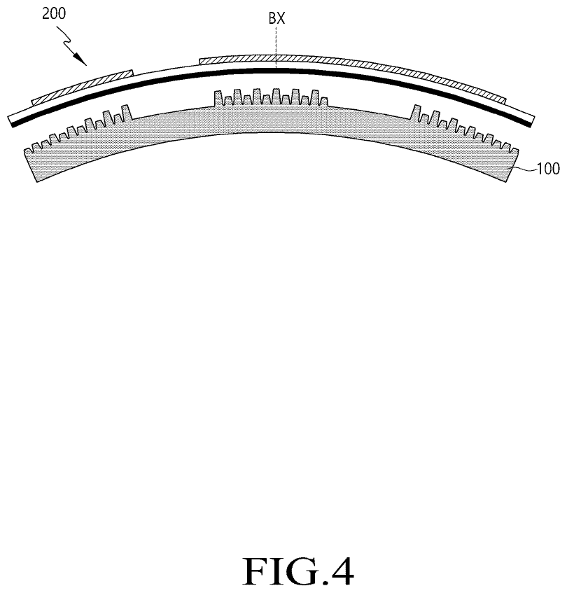

FIGS. 4 to 6 are cross-sectional views illustrating a shape of a protrusion pattern 121 according to a curve structure of a flexible display device.

As illustrated in FIGS. 4 to 6, the adhesive portion 120 may include a pattern area in which the protrusion pattern 121 is formed and a non-pattern area in which the protrusion pattern 121 is not formed. This is because the protrusion pattern 121 may easily discharge air bubbles, but the contact area with the object to be attached may be reduced, thereby deteriorating attachment performance. Accordingly, when the protrusion pattern 121 is not formed on the entire front surface of the adhesive portion 120 and the protrusion pattern 121 is formed only on a portion thereof, air bubbles may be removed through the pattern area during the attachment process, and adhesive strength may be enhanced through the non-pattern area.

In addition, the display panel assembly 200 may be formed to be bendable, and a curve may be formed on at least a portion of the display panel assembly 200, and the height and width of the protrusion pattern 121 may vary depending on the shape of the curve. Hereinafter, the structure of the protrusion pattern 121 according to the curve shape of the display panel assembly 200 is described with reference to FIGS. 4 to 6.

As illustrated in FIG. 4, the central portion of the display panel assembly 200 may be bent to form curves symmetrical to two opposite sides with respect to the bending axis BX. Further, the height of the protrusion pattern 121 formed on the adhesive member 100 may be formed to decrease toward the outside from the portion facing the bending axis BX.

As described above, when the micro pattern is formed to decrease in height outward from the bending axis BX according to the curve shape, the portion where the bending axis BX is positioned may be prevented or reduced from being lifted, bringing the adhesive member 100 into tight contact with the display panel assembly 200.

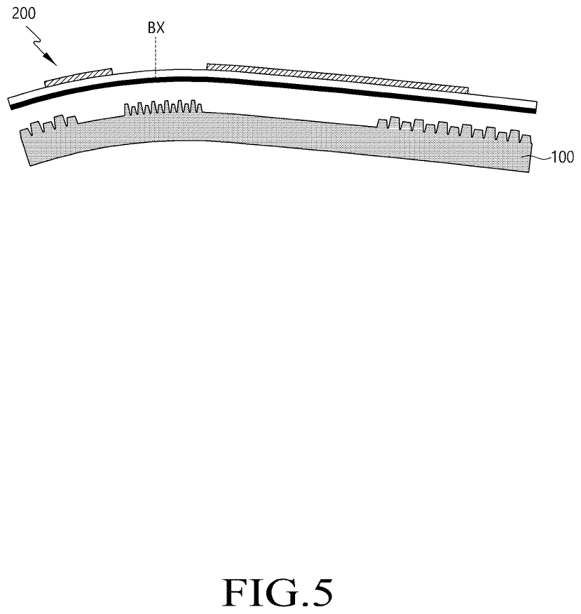

As illustrated in FIG. 5, one side portion of the display panel assembly 200 may be bent to form an asymmetrical curve with respect to the bending axis BX. Further, the protrusion pattern 121 formed on the adhesive member 100 may be formed to increase in width outward from the portion facing the bending axis BX.

In other words, by increasing the density of the protrusion pattern 121 in a further bent portion due to bending, air bubbles may be discharged more seamlessly during the attachment process of the adhesive member 100 and adhesion may be enhanced. Further, in order to prevent or reduce the bending axis BX from being lifted from the portion where the bending axis BX is positioned, a height of the protrusion pattern 121 formed on the portion of the bending axis BX may be larger than a height of the protrusion pattern 121 formed outside the bending axis BX.

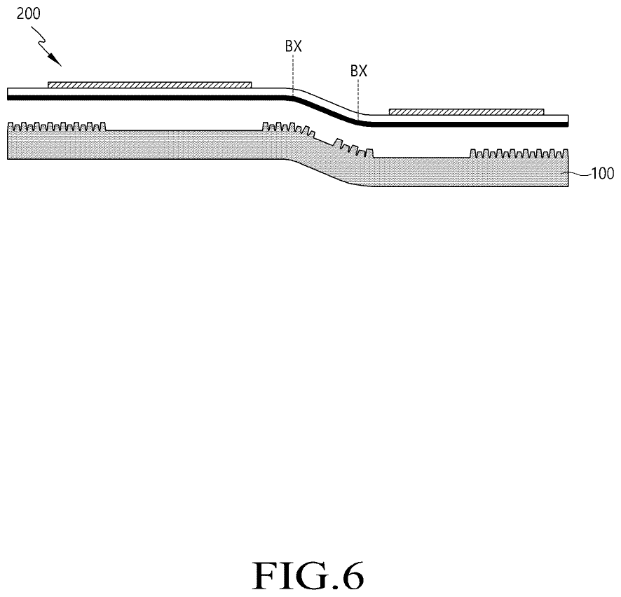

As illustrated in FIG. 6, two or more portions of the display panel assembly 200 may be bent to form at least one of a convex curve and a concave about each bending axis BX. The width of the protrusion pattern 121 formed at the portion facing the convex curve may be smaller than the width of the protrusion pattern 121 formed on another portion facing the concave curve.

In other words, by forming the adhesive member 100 to differ in density according to the curvature direction of the curve, air bubbles may be discharged more seamlessly during the attachment process of the adhesive member 100, and adhesion may be enhanced.

As described above, as a micro irregular pattern is formed on the surface of the adhesive member 100 so that air bubbles may be discharged, it is possible to prevent or reduce air bubbles from being formed between the display panel assembly 200 and the adhesive member 100 when the adhesive member 100 is attached to the display panel assembly 200 having a large area.

Further, by minimizing or reducing air bubbles formed between the display panel assembly 200 and the adhesive member 100, delamination and deterioration of visibility of the display panel assembly 200 due to the occurrence of air bubbles may be prevented or reduced.

Embodiments of the disclosure described above are briefly described below.

According to embodiments of the disclosure, an adhesive member for coupling a display panel assembly implementing an image and a supporting frame supporting a rear surface of the display panel assembly may comprise a base portion and an adhesive portion formed on one side or two opposite sides of the base portion and provided with a protrusion pattern having different heights.

According to embodiments of the disclosure, the protrusion pattern may be formed by forming irregularities in which a plurality of protrusions are spaced apart from each other.

According to embodiments of the disclosure, the protrusion pattern may be formed in a tapered shape that decreases in width toward an end thereof.

According to embodiments of the disclosure, an end portion of the protrusion pattern may be formed in a straight line or dome shape.

According to embodiments of the disclosure, the protrusion pattern may include a plurality of first protrusions protruding in one direction and spaced apart from each other and a second protrusion disposed between the first protrusions and protruding to a size smaller than a height of the first protrusion.

According to embodiments of the disclosure, a height of the second protrusion may be formed to be at least half of a height or less of the first protrusion.

According to embodiments of the disclosure, a sum of a maximum width of the first protrusion and a maximum width of the second protrusion may be at least 1,200 μm or less.

According to embodiments of the disclosure, the adhesive portion may include a pattern area in which the protrusion pattern is formed and a non-pattern area in which the protrusion pattern is not formed.

According to embodiments of the disclosure, the display panel assembly may be formed to be bendable to have a curve formed in at least a portion thereof. The protrusion pattern may vary in height and width depending on the curve shape.

According to embodiments of the disclosure, a display device may comprise a display panel assembly implementing an image, a supporting frame supporting a rear surface of the display panel assembly, and an adhesive member disposed between the display panel assembly and the supporting frame to couple the display panel assembly and the supporting frame, wherein the adhesive member has a protrusion pattern having different heights on one or two opposite surfaces thereof.

According to embodiments of the disclosure, the adhesive member may include a base portion and an adhesive portion formed on one side or two opposite sides of the base portion and provided with the protrusion pattern.

According to embodiments of the disclosure, the protrusion pattern may be formed by forming irregularities in which a plurality of protrusions are spaced apart from each other.

According to embodiments of the disclosure, each protrusion pattern may be formed in a tapered shape having a width decreasing toward the end, and the end portion may be formed in a straight line or dome shape.

According to embodiments of the disclosure, the protrusion pattern may include a plurality of first protrusions protruding in one direction and spaced apart from each other and a second protrusion disposed between the first protrusions and protruding to a size smaller than a height of the first protrusion. A height of the second protrusion may be formed to be at least half of a height or less of the first protrusion.

According to embodiments of the disclosure, the adhesive portion may include a pattern area in which the protrusion pattern is formed and a non-pattern area in which the protrusion pattern is not formed.

According to embodiments of the disclosure, a center portion of the display panel assembly may be bent to form a curve symmetrical to two opposite sides with respect to a bending axis, and the protrusion pattern formed on the adhesive member may be formed to decrease in height outward from a portion facing the bending axis.

According to embodiments of the disclosure, one side portion of the display panel assembly may be bent to form an asymmetric curve with respect to a bending axis. The protrusion pattern formed on the adhesive member may be formed to increase in width outward from a portion facing the bending axis.

According to embodiments of the disclosure, a height of the protrusion pattern formed at a portion of the bending axis may be larger than a height of the protrusion pattern formed outside the bending axis.

According to embodiments of the disclosure, two or more portions of the display panel assembly may be bent to form at least one of a convex curve and a concave curve about each bending axis. A width of the protrusion pattern formed on a portion facing the convex curve may be smaller than a width of the protrusion pattern formed on another portion facing the concave curve.

According to embodiments of the disclosure, a heat dissipation plate may be further provided on the rear surface of the display panel assembly. The adhesive member may be disposed between the heat dissipation plate and the supporting frame.

It will be apparent to those skilled in the art that various modifications and variations can be made in the adhesive member and the display device including the same of the present disclosure without departing from the technical idea or scope of the disclosure. Thus, it is intended that the present disclosure cover the modifications and variations of this disclosure provided they come within the scope of the appended claims and their equivalents.

What is claimed:

1. An adhesive member for coupling a display panel assembly implementing an image and a supporting frame supporting a rear surface of the display panel assembly, comprising:
a base portion; and
an adhesive portion formed on one side or two opposite sides of the base portion and provided with a protrusion pattern of an uneven structure.

2. The adhesive member of claim 1, wherein the protrusion pattern has different heights.

3. The adhesive member of claim 1, wherein the protrusion pattern is formed by forming irregularities in which a plurality of protrusions are spaced apart from each other.

4. The adhesive member of claim 1, wherein the protrusion pattern is formed in a tapered shape that decreases in width toward an end thereof.

5. The adhesive member of claim 1, wherein an end portion of the protrusion pattern is formed in a straight line or dome shape.

6. The adhesive member of claim 1, wherein the protrusion pattern includes:
a plurality of first protrusions protruding in one direction and spaced apart from each other; and
a second protrusion disposed between the first protrusions and protruding to a size smaller than a height of the first protrusion.

7. The adhesive member of claim 6, wherein a height of the second protrusion is formed to be at least half of a height or less of the first protrusion.

8. The adhesive member of claim 6, wherein a sum of a maximum width of the first protrusion and a maximum width of the second protrusion is at least 1,200 μm or less.

9. The adhesive member of claim 1, wherein the adhesive portion includes a pattern area in which the protrusion pattern is formed and a non-pattern area in which the protrusion pattern is not formed.

10. The adhesive member of claim 1, wherein the display panel assembly is formed to be bendable to have a curve formed in at least a portion thereof, and
wherein the protrusion pattern varies in height and width depending on a shape of the curve.

11. The adhesive member of claim 10, wherein a portion of the display panel assembly is bent to form a curve symmetrical to two opposite sides with respect to a bending axis, and
wherein the protrusion pattern formed on the adhesive member is formed to decrease in height outward from a portion facing the bending axis.

12. The adhesive member of claim 10, wherein one side portion of the display panel assembly is bent to form an asymmetric curve with respect to a bending axis, and
wherein the protrusion pattern formed on the adhesive member is formed to increase in width outward from a portion facing the bending axis.

13. The adhesive member of claim 12, wherein a height of the protrusion pattern formed at a portion of the bending axis is larger than a height of the protrusion pattern formed outside the bending axis.

14. The adhesive member of claim 10, wherein two or more portions of the display panel assembly are bent to form at least one of a convex curve and a concave curve about each bending axis, and
wherein a width of the protrusion pattern formed on a portion facing the convex curve is smaller than a width of the protrusion pattern formed on another portion facing the concave curve.

15. A display device, comprising:
a display panel assembly implementing an image;
a supporting frame supporting a rear surface of the display panel assembly; and
an adhesive member disposed between the display panel assembly and the supporting frame to couple the display panel assembly and the supporting frame,
wherein the adhesive member has a protrusion pattern of an uneven structure on one or two opposite surfaces thereof.

16. The display device of claim 15, wherein the protrusion pattern has different heights.

17. The display device of claim 15, wherein the adhesive member includes a base portion and an adhesive portion formed on one side or two opposite sides of the base portion and provided with the protrusion pattern.

18. The display device of claim 15, wherein the protrusion pattern is formed by forming irregularities in which a plurality of protrusions are spaced apart from each other.

19. The display device of claim 15, wherein the protrusion pattern is formed in a tapered shape having a width decreasing toward an end thereof, and wherein the end of the protrusion pattern is formed in a straight line or dome shape.

20. The display device of claim 15, wherein the protrusion pattern includes a plurality of first protrusions protruding in one direction and spaced apart from each other and a second protrusion disposed between the first protrusions and protruding to a size smaller than a height of the first protrusion, and
wherein a height of the second protrusion is formed to be at least half of a height or less of the first protrusion.

21. The display device of claim 17, wherein the adhesive portion includes a pattern area in which the protrusion pattern is formed and a non-pattern area in which the protrusion pattern is not formed.

22. The display device of claim 15, wherein a portion of the display panel assembly is bent to form a curve symmetrical to two opposite sides with respect to a bending axis, and
wherein the protrusion pattern formed on the adhesive member is formed to decrease in height outward from a portion facing the bending axis.

23. The display device of claim 15, wherein one side portion of the display panel assembly is bent to form an asymmetric curve with respect to a bending axis, and
wherein the protrusion pattern formed on the adhesive member is formed to increase in width outward from a portion facing the bending axis.

24. The display device of claim 17, wherein a height of the protrusion pattern formed at a portion of the bending axis is larger than a height of the protrusion pattern formed outside the bending axis.

25. The display device of claim 15, wherein two or more portions of the display panel assembly are bent to form at least one of a convex curve and a concave curve about each bending axis, and
wherein a width of the protrusion pattern formed on a portion facing the convex curve is smaller than a width of the protrusion pattern formed on another portion facing the concave curve.

26. The display device of claim 15, wherein a heat dissipation plate is further provided on the rear surface of the display panel assembly, and wherein the adhesive member is disposed between the heat dissipation plate and the supporting frame.
